(19) United States
(12) Patent Application Publication
(10) Pub. No.: US 2013/0340939 A1
(43) Pub. Date: Dec. 26, 2013

(54) SYSTEM FOR SUBSTRATE HANDLING AND PROCESSING

(71) Applicant: TEL Solar AG, Trubbach (CH)

(72) Inventors: Christian EGLI, Sevelen (CH); Damian EHRENSPERGER, Basel (CH)

(21) Appl. No.: 13/922,594

(22) Filed: Jun. 20, 2013

Related U.S. Application Data
(60) Provisional application No. 61/662,435, filed on Jun. 21, 2012.

(51) Int. Cl. H01J 37/20

(52) U.S. Cl. CPC H01J 37/20
USPC 156/345.31; 118/719

(57) ABSTRACT

This disclosure relates to a substrate processing system for substrates with a surface area of greater than 1 m². The system may include, but is not limited to, load locks and processing chambers that are aligned in a vertical manner. For example, the load locks may be arranged above or below the processing chambers. In turn, the processing chambers may be stacked upon each other in a vertical arrangement. A transfer chamber may also be used to transfer substrates between the load locks and the process chambers. The substrate transfer process may be done under vacuum conditions.

### CROSS REFERENCE TO RELATED APPLICATIONS

This application claims priority to provisional application 61/662,435 filed on Jun. 21, 2012. The provisional application is incorporated by reference in its entirety into this application.

### TECHNICAL FIELD

This disclosure generally relates to a system that handles and processes substrates, which have a surface area of greater than 1 m², using plasma processing.

### BACKGROUND

Cluster tools with multiple process chambers may enable vacuum processing that may reduce substrate contamination. However, when one chamber process is significantly longer than the other processes on the cluster tool a bottle neck may develop. The bottle neck may decrease efficiency or throughput and drive up manufacturing cost. Generally, cluster tools may be arranged in a radial manner that limits the ability to increase the number of process chambers. Hence, to increase processing capacity a factory owner may have to purchase additional cluster tools instead of adding process chambers to existing cluster tools.

### BRIEF DESCRIPTION OF THE FIGURES

The features within the drawings are numbered and are cross-referenced with the written description. Generally, the first numeral reflects the drawing number where the feature was first introduced, and the remaining numerals are intended to distinguish the feature from the other notated features within that drawing. However, if a feature is used across several drawings, the number used to identify the feature in the drawing where the feature first appeared will be used. Reference will now be made to the accompanying drawings, which are not necessarily drawn to scale and wherein:

FIG. 1 is a simplified block diagram of a representative substrate processing system that may include one or more process chambers, one or more load lock chambers, one or more transfer chambers, and/or a substrate-loading device as described in one or more embodiments of the disclosure.

FIG. 2 is a simplified block diagram of a representative docking station between the transfer chamber and the process chamber or the load lock chamber as described in one or more embodiments of the disclosure.

### SUMMARY

Embodiments of the invention are described more fully hereinafter with reference to the accompanying drawings, in which embodiments of the disclosure are shown. This disclosure may, however, be embodied in many different forms and should not be construed as limited to the embodiments set forth herein; rather, these embodiments are provided so that this disclosure will be thorough and complete, and will fully convey the scope of the disclosure to those skilled in the art.

Embodiments described in this disclosure may include an arrangement of processing and handling devices to improve efficiency for processing substrates with large surface areas. In one embodiment, the system may include a plurality of process chambers, at least two load lock chambers, and at least one transfer chamber that may enable the transfer of large substrates under vacuum. The process chambers and load lock chambers may be arranged in a vertical configuration. The process chambers and load lock chambers may be aligned along a vertical axis. In one instance, the process chambers may be located above the load lock chambers. However, in another embodiment, the load lock chambers may be subjacent to the process chambers. In each of the aforementioned embodiments, the system may also include a transfer chamber that moves vertically between the process chambers and the load lock chambers delivering substrates to the each of the components of the system.

The delivery or transfer of substrates within the system may occur under vacuum conditions maintained by the components of the system. In one embodiment, the load lock chamber may be loaded with a substrate and placed under vacuum. The transfer chamber may dock with the load chamber and retrieve the substrate from the load lock chamber while maintaining vacuum during the substrate transfer. The docking chamber may include a space that may be maintained at a pressure less than atmospheric pressure. The space may also include enough room for the docking doors of the load lock chamber and the transfer chamber to be moved in a way that enables a substrate to be moved between the load lock and the transfer chamber. The process chamber may also include a docking station that enables the transfer chamber to provide the substrate to the process chamber under vacuum conditions. Upon process completion, the transfer chamber may receive the substrate from the process chamber and provide the substrate back to the load lock or another process chamber for further processing.

Example embodiments of the disclosure will now be described with reference to the accompanying figures.

### DETAILED DESCRIPTION

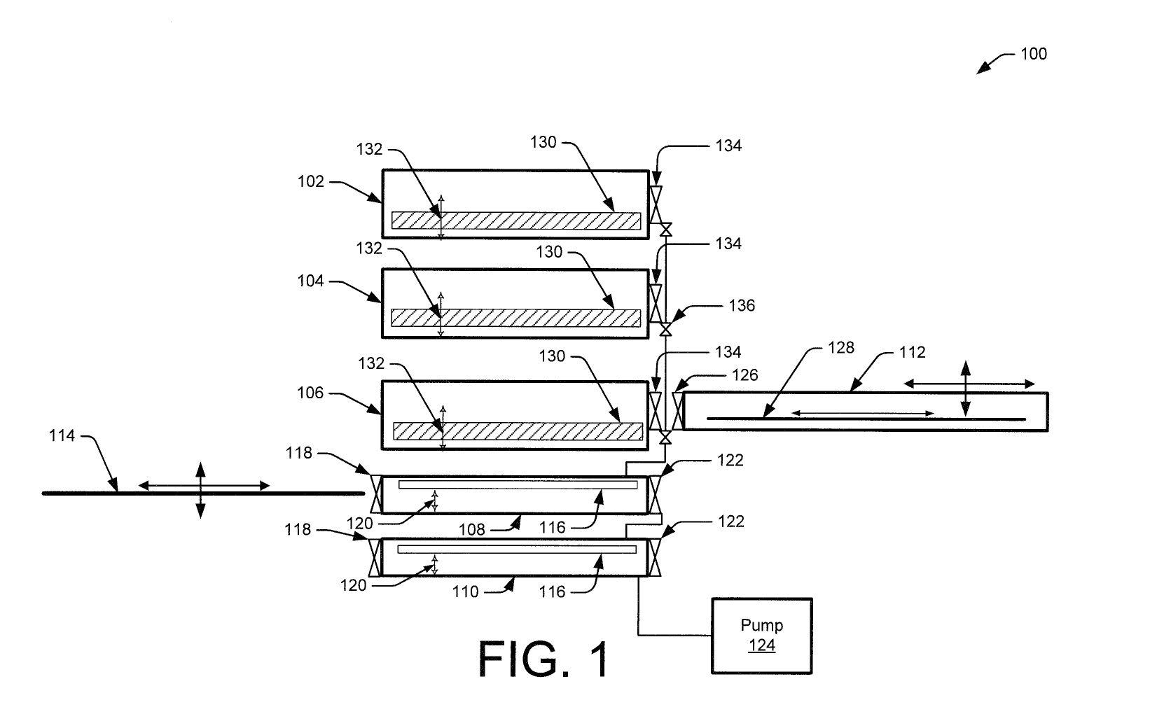

FIG. 1 illustrates a side view of a substrate processing system 100 that may include process chambers 102, 104, 106, load lock chambers 108, 110, a transfer chamber 112, and/or a substrate-loading device 114. The system 100 may be used to deposit thin films on substrates that have a surface area greater or equal to 1 m². The arrangement of the system 100 components may be optimized to enable efficient transfer of substrates and adding process chambers (e.g., process chamber 102) and/or load locks (e.g., load locks 108). In another embodiment, a process chamber 102 may be configured to perform plasma etching of the substrates.

In one embodiment, the arrangement of the system 100 components may be optimized to reduce the footprint of the system 100. The footprint being the amount of floor space the system 100 may occupy when being used to process substrates. The footprint may include the floor space that makes contact with the bottom of the system or the footprint may include the floor space that is consumed by the perimeter of the tool. The perimeter of the tool may include portions of the system that may not be in direct physical contact with the floor. For example, the footprint may include the shadow of the system 100 when a light is shown from above down onto the system 100.

In one embodiment, the process chambers 102, 104, 106 may be arranged in a vertical manner to reduce their footprint or the amount of floor space that may be used by the system 100. For example, the first process chamber 102 may be placed above the second process chamber 104. Further, the third process chamber 106 may be placed below the second process chamber 104. In this stacked arrangement, additional process chambers may be added to the system 100 without increasing the footprint of the system or by increasing the footprint of the system 100 by a negligible amount compared to the size of the process chambers.

In this embodiment, the load locks 108, 110 may be arranged below the stacked arrangement of process chambers 102, 104, 106, as shown in FIG. 1. However, in other embodiments, the load locks 108, 110 may be arranged above the stacked process chambers 102, 104, 106 or they may be placed in between the stacked process chambers 102, 104, 106. For example, the load locks 108, 110 may be near one another, as shown in FIG. 1, or they may be separated from each other by one or more process chambers 102, 104, 106.

The load locks 108, 110 may be configured to receive substrates 116 from a substrate-loading device 114. The substrate-loading device 114 may move up and down to align with the incoming ports 118 of the load locks 108, 110. The substrate-loading device 114 may also move left to right to insert or retrieve substrates 116 in the load locks 108, 110. The substrate-loading device 114 may pick or place substrates 116 from lift pins 120 that may be used to support the substrates in the load locks 108, 110. In one embodiment, the load locks 108, 110 may be designated for certain substrate movements. For example, the top load lock 108 may be used for incoming substrates while the bottom load lock 110 may be used for outgoing substrates. The load locks 108, 110 may also include heating and cooling capabilities to control the temperatures of the substrates 116. For example, the substrate 116 may be heated prior to transferring to the transfer chamber 112. The heating may be done using a heating element installed in the load lock 108 or by flowing a heated gas into the load lock 108. In the alternative, the load lock 108 may be cooled by a heat transfer system that removes heat away from the load lock 108. The heat transfer system may include, but is not limited to, a liquid cooling system that circulates a cool liquid around the load lock to extract heat and lower the temperature of the load lock. In another embodiment, the cooling system may include, but is not limited to, flowing a relatively cool gas into the load lock 108 and exhausting the gas away from the load lock 108.

The load locks 108, 110 may also include an outgoing port 122 that may interface with the transfer chamber 112. The outgoing ports 122 may include a space (not shown) that may be evacuated to a lower pressure using a pump 124. The load locks 108, 110 may also be pumped down to a lower pressure using the pump 124. In certain embodiments, the pump 124 may also pump down the transfer chamber 112 when the transfer chamber is docked with at least one of the load locks 108, 110. In another embodiment, the transfer chamber 112 may be pumped down by a separate pump (not shown) or through one of the process chambers 102, 104, 106 that may be connected to a pump (not shown).

The transfer chamber 112 may transfer substrates 116 between the load locks 108, 110 and the process chambers 102, 104, 106. The transfer chamber may be raised and lowered to align a transfer docking mechanism 126 that may couple with the load locks 108, 110 and the process chambers 102, 104, 106, prior to transferring the substrates 116. A substrate transfer device 128 may be used to move the substrate 116 between the transfer chamber 112 and the load locks 108, 110 or the process chambers 102, 104, 106. The substrate transfer device 128 may move frontwards and backwards, as shown in FIG. 1, to pick up or place substrates 116 in the load locks 108, 110 or the process chambers 102, 104, 106.

The process chambers 102, 104, 106 may be used to deposit or etch very large substrates of at least 1 m² using plasma processing. In one instance, the system 100 may perform Plasma-Enhanced Chemical Vapor deposition (PECVD) using a plasma electrode (not shown) in conjunction with gases provided by a gas delivery system (not shown). The process chambers 102, 104, 106 may be maintained at vacuum during processing and substrate transferring by a vacuum system (not shown). The process chambers 102, 104, 106 may also include a substrate pedestal 130 that may support the substrate 116 during processing. Lift pins 132 may lift and place the substrate 116 onto the substrate transfer device 128 to facilitate substrate 116 transfers between the process chamber 102, 104, 106 and the transfer chamber 112. In another embodiment, the system 100 may be used for plasma etching using the plasma electrode and gases provided by a gas delivery system.

A docking station mechanism 134 may be coupled or integrated into each of the process chambers 102, 104, 106 to enable substrate 116 transfers, under vacuum, to and from the transfer chamber 112. The docking station mechanism 134 may include a pump assembly 136 that may enable each of the docking station mechanisms 134 to be pumped down independently when the docking station may be coupled to the transfer docking mechanism 126. In the FIG. 1 embodiment, the pump 124 may enable the evacuation of gas between the docking station mechanism 134 and the transfer docking mechanism 126.

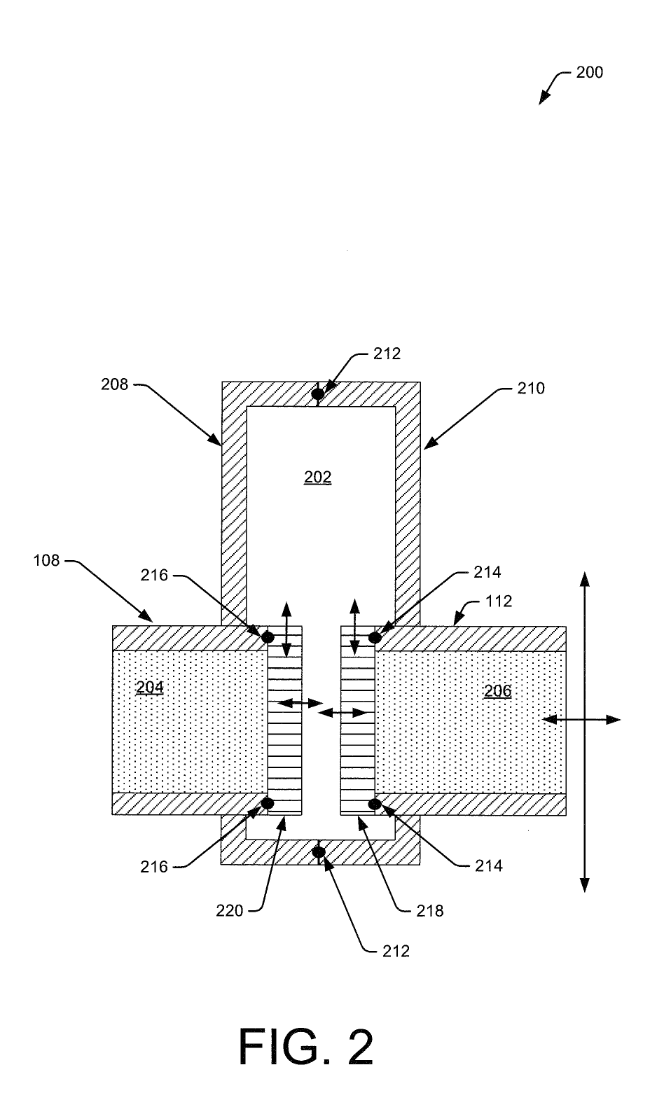

FIG. 2 is a simplified block diagram of a representative docking station 200 between the transfer chamber 112 and the process chamber 102 or the load lock chamber 108. The docking station 200 may enable substrate transfer, under vacuum, between the load lock 108 and the transfer chamber 112. For example, the docking station 200 may include an evacuation area 202 that may be pumped down to low vacuum. The evacuation area 202 may be pumped down to a similar pressure found in the load lock 108 and the transfer chamber 112. The evacuation area 202 may be formed by a load lock enclosure component 208 that may be sealed against a transfer enclosure component 210 using a seal 212 that may be coupled to either or both of the components 208, 210. The transfer chamber 112 may include a transfer door 218 that may be sealed against the transfer chamber 112 using a gasket or o-ring 214. The load lock 108 may also include a load lock door 220 that may be sealed against the load lock 108 using a gasket or o-ring 216.

In one embodiment, the transfer of the substrates may occur after the evacuation area 202 is formed by sealing the transfer enclosure component 210 against the load lock enclosure component 208. The evacuation area 202 may be pumped down to a pressure that may be substantially similar to the load lock evacuation area 204 and the transfer chamber evacuation area 206. When the pressure between all of the evacuation areas 202, 204, 206 are similar, the load lock door 220 and the transfer door 218 may be moved out and up into the evacuation area 202. While the load lock door 220 and the transfer door 218 are in the out and up position, the transfer chamber 112 may insert or retrieve the substrate 116 from the load lock 108. In FIG. 2, the load lock 108 and the transfer chamber 112 are shown in the closed position. When the transfer chamber 112 receives the substrate 116, the load lock door 220 and the transfer door 218 may return to the closed position. The transfer chamber enclosure component 210 may separate from the load lock enclosure component 208. The transfer chamber 112 may then move vertically to a process chamber 102 to begin transferring the substrate 116. The process chamber 102 may also include a process chamber enclosure component (not shown) that may be similar to the load lock enclosure component 208. In this way, the transfer of the substrate 116 between the process chamber 102 and the transfer chamber 112 may occur by using similar techniques described above for the transfer of the substrate 116, under vacuum, between the load lock 108 and the transfer chamber 112.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation. In the use of such terms and expressions, there is no intention of excluding any equivalents of the features shown and described (or portions thereof), and it is recognized that various modifications are possible within the scope of the claims. Other modifications, variations, and alternatives are also possible. Accordingly, the claims are intended to cover all such equivalents.

While certain embodiments of the invention have been described in connection with what is presently considered to be the most practical and various embodiments, it is to be understood that the invention is not to be limited to the disclosed embodiments, but on the contrary, is intended to cover various modifications and equivalent arrangements included within the scope of the claims. Although specific terms are employed herein, they are used in a generic and descriptive sense only, and not for purposes of limitation.

1. A device, comprising:
three or more substrate processing modules that are arranged and aligned with each other in a vertical orientation;
one or more transfer modules that move vertically to transfer one or more substrates to the three or more substrate processing modules;
two or more load lock modules that are subjacent and aligned in a vertical orientation with the three or more substrate processing modules, the one or more transfer modules can transfer the substrates to and from the two or more load lock modules.

2. The device of claim 1, wherein the three or more substrate processing modules comprise transfer ports that enable placement and removal of the substrates from the respective substrate processing module, the transfer ports for each substrate processing module are aligned within a substantially similar vertical plane.

3. The device of claim 1, wherein the device comprises a first load lock that is only used to transfer substrates to the one or more transfer modules and a second load lock that is only used to receive substrates from the one or more transfer modules.

4. The device of claim 1, wherein the two or more load lock modules comprise a first transfer port and a second transfer port that are parallel to each other, the first transfer port enables the transfer of the substrates in and out of the device, and the second transfer port enables the transfer of the substrate to or from the one or more transfer modules.

5. The device of claim 1, wherein the two or more load lock modules can preheat the substrate prior to processing in the at least one of the three or more substrate processing modules.

6. The device of claim 1, wherein the three or more substrate processing modules are coupled to a pump that is used to pump down the one or more transfer modules when they are coupled to at least one of the three or more substrate processing modules.

7. The device of claim 1, wherein the one or more transfer modules each comprise a substrate transfer device that transfer transfers at least one substrate between the two or more load lock modules and the three or more substrate processing modules.

8. The device of claim 7, wherein the three or more substrate processing modules each comprise lift pins to lift the substrate off of the substrate transfer device.

9. The device of claim 7, wherein the two or more lock modules each comprise lift pins to lift the substrate off of the substrate transfer device.

10. A device, comprising:
three or more substrate processing modules that are arranged and aligned with each other in a vertical orientation;
a transfer module that moves vertically to transfer one or more substrates to the three or more substrate processing modules;
two or more load lock modules that are subjacent and aligned in a vertical orientation with the three or more substrate processing modules, the two or more load lock modules can transfer the substrates to and from the transfer modules.

11. The device of claim 10, wherein the three or more substrate processing modules comprise transfer ports that enable placement and removal of the substrates from the respective substrate processing module, the transfer ports for each substrate processing module are aligned within a substantially similar vertical plane.

12. The device of claim 10, wherein the two or more load locks comprise a first load lock that is only used to transfer substrates to the transfer module and a second load lock that is only used to receive the substrates from the transfer module.

13. The device of claim 10, wherein the two or more load lock modules comprise a first transfer port and a second transfer port that are parallel to each other, the first transfer port enables the transfer of the substrates in and out of the device, and the second transfer port enables the transfer of the substrate to and from the transfer module.

14. The device of claim 10, wherein the two or more load lock modules can preheat the substrates prior to processing the substrates in the at least one of the three or more substrate processing modules.

15. The device of claim 10, wherein the three or more substrate processing modules are coupled to a pump that is used to pump down the transfer module when the transfer module is coupled to at least one of the three or more substrate processing modules.

16. The device of claim 10, wherein the transfer module comprises a substrate transfer device that transfers at least one substrate between the two or more load lock modules and the three or more substrate processing modules.

17. The device of claim 16, wherein the three or more substrate processing modules each comprise lift pins to lift the substrate off of the substrate transfer device.

18. The device of claim 17, wherein the two or more load load modules each comprise lift pins to lift the substrate off of the substrate transfer device.

19. The device of claim 10, wherein the two or more load lock modules, the three or more substrate processing modules, and the transfer module are configured to handle the substrates in a vertical configuration.

20. The device of claim 10, wherein the two or more load lock modules, the three or more substrate processing modules, and the transfer module are configured to handle the substrates in a horizontal configuration.
